(19) United States
(12) Patent Application Publication
(10) Pub. No.: US 2021/0057404 A1
(43) Pub. Date: Feb. 25, 2021

(54) ON-DIE ELECTROSTATIC DISCHARGE PROTECTION

(71) Applicant: QUALCOMM Incorporated, San Diego, CA (US)

(72) Inventors: Kai LIU, Phoenix, AZ (US); Xiaoju YU, San Diego, CA (US); Ye LU, San Diego, CA (US)

(21) Appl. No.: 16/990,418

(22) Filed: Aug. 11, 2020

Related U.S. Application Data
(60) Provisional application No. 62/890,467, filed on Aug. 22, 2019.

(51) Int. Cl. H01L 27/01; H01L 27/02; H01L 23/60

(52) U.S. Cl. CPC H01L 27/016; H01L 23/60; H01L 27/0288

(57) ABSTRACT

Disclosed are devices and methods for on-die electrostatic discharge (ESD) protection in an electronic device. Aspects disclosed include an electronic device including a protected circuit disposed within a die having a first port and a second port. A first inductor is also disposed within the die and is electrically coupled to the first port. A second inductor is also disposed within the die and electrically coupled to the second port. The first inductor and the second inductor are routed in close proximity and are configured so the first inductor is out of phase with the second inductor.

### CROSS-REFERENCE TO RELATED APPLICATIONS

The present application for patent claims the benefit of Provisional Application No. 62/890,467 entitled “ON-DIE ELECTROSTATIC DISCHARGE PROTECTION” filed Aug. 22, 2019, assigned to the assignee hereof and expressly incorporated herein by reference in its entirety.

### FIELD OF DISCLOSURE

The present disclosure is related to on-die electrostatic discharge (ESD) protection of electronic devices and in further aspects to filters or other circuitry embedded in a package or integrated circuit.

### BACKGROUND

Integrated circuit technology has achieved great strides in advancing computing power through miniaturization of active components. Integrated passive components have also been miniaturized. As frequencies and data rates get higher, there is a need for further miniaturization of integrated passive components, for example, filters which include inductive (L) and capacitive (C) elements in integrated circuit devices. Additionally, to improve quality of received signals, certain components of a mobile device may be formed on an insulating substrate (e.g., glass substrate). For example, a circuit component may be formed on a glass substrate to “isolate” the component in order to reduce effects of noise from other components of the mobile device.

In some applications, integrated passive devices (IPD) based on inductor and capacitor components usually suffer from poor ESD performance, due to a lack of ESD protection circuits on the die. However, adding ESD protection elements in a module-level (e.g., inductors) increases the module size, and would not help if the integrated passive device (IPD) dies are already ESD-damaged before the insertion of the ESD inductor in the module. Providing ESD protection on-die can provide protection of on-die circuits and provide yield improvement. Accordingly, there is a need to implement ESD protection on a die-level.

### SUMMARY

The following summary identifies some features and is not intended to be an exclusive or exhaustive description of the disclosed subject matter. Additional features and further details are found in the detailed description and appended claims. Inclusion in the Summary is not reflective of importance. Additional aspects will become apparent to persons skilled in the art upon reading the following detailed description and viewing the drawings that form a part thereof.

In accordance with the various aspects disclosed herein, at least one aspect includes, an electronic device including: a protected circuit disposed within a die having a first port and a second port; a first inductor disposed within the die, electrically coupled to the first port; and a second inductor disposed within the die, electrically coupled to the second port, where the first inductor and the second inductor are routed in close proximity and are configured so the first inductor is out of phase with the second inductor and where the first inductor and the second inductor are both formed around the protected circuit.

In accordance with the various aspects disclosed herein, at least one aspect includes, a method for fabricating an electronic device including: fabricating a protected circuit disposed within a die having a first port and a second port; forming a first inductor disposed within the die, electrically coupled to the first port; and forming a second inductor disposed within the die, electrically coupled to the second port, where the first inductor and the second inductor are routed in close proximity and configured to have the first inductor out of phase with the second inductor, where the first inductor and the second inductor are both formed around the protected circuit.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of embodiments of the present disclosure and are provided solely for illustration of the various aspects disclosed and not limitation thereof.

FIG. 1A is an illustration depicting aspects of an integrated passive device according to aspects of the disclosure.

FIG. 1B is an illustration depicting a portion of the integrated passive device of FIG. 1A according to aspects of the disclosure.

FIG. 1C is an illustration depicting aspects of a metal insulator metal (MIM) capacitor failure according to aspects of the disclosure.

FIG. 2 is an illustration depicting a triplexer circuit according to aspects of the disclosure.

FIG. 3 is an illustration of a cross-section of a portion of a die according to aspects of the disclosure.

FIG. 4 is an illustration of images of cross-section portions of another die according to aspects of the disclosure.

FIG. 5 is an illustration depicting aspects of a simplified circuit diagram according to aspects of the disclosure.

FIG. 6 is an illustration depicting aspects of a layout for inductors for ESD protection according to aspects of the disclosure.

FIG. 7 is an illustration depicting a comparison of a conventional circuit layout and a circuit layout with on-die ESD protection according to aspects of the disclosure.

FIG. 8 is an illustration depicting a comparison of performance simulations of a conventional circuit layout and a circuit layout with on-die ESD protection according to aspects of the disclosure.

FIG. 9 is an illustration depicting several views of a circuit layout with on-die ESD protection according to aspects of the disclosure.

FIG. 10 is an illustration depicting an exemplary communication system according to aspects of the disclosure.

FIG. 11 is a flowchart illustrating aspects of methods according to aspects of the disclosure.

FIG. 12A is an illustration of portions of a fabrication process according to aspects of the disclosure.

FIG. 12B is a further illustration of portions of a fabrication process according to aspects of the disclosure.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

As discussed in the foregoing, there is a need to implement ESD protection by including ESD inductors on a die-level. In order to reduce the die size, a new concept of inductor layout is provided. In one example, the ESD inductors at the input and output ports are electromagnetically coupled to each other, e.g., routed in close proximity and out of electrical phase, e.g., with current-flows in opposite directions. Additionally, the ESD inductors are configured on the die to have a minimum impact on the intrinsic performance of the protected circuit (e.g., one or more filters, diplexers, triplexers, etc.). The term “protected” is used herein to note that ESD events and subsequent failures are mitigated on the circuit being protected by the ESD inductors.

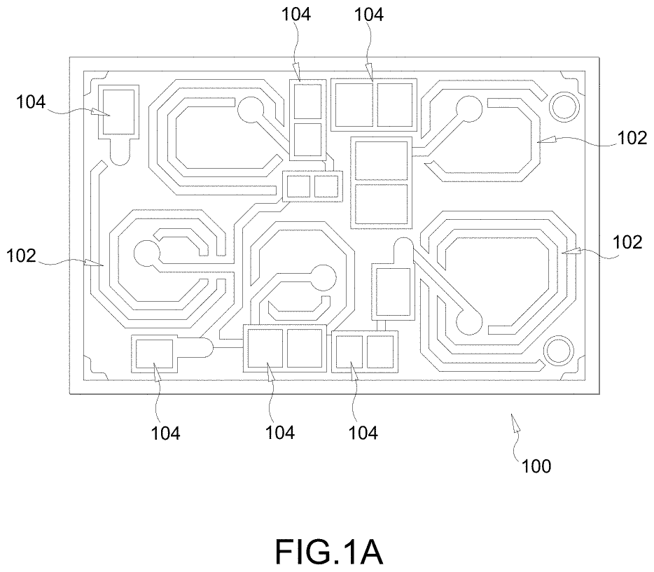

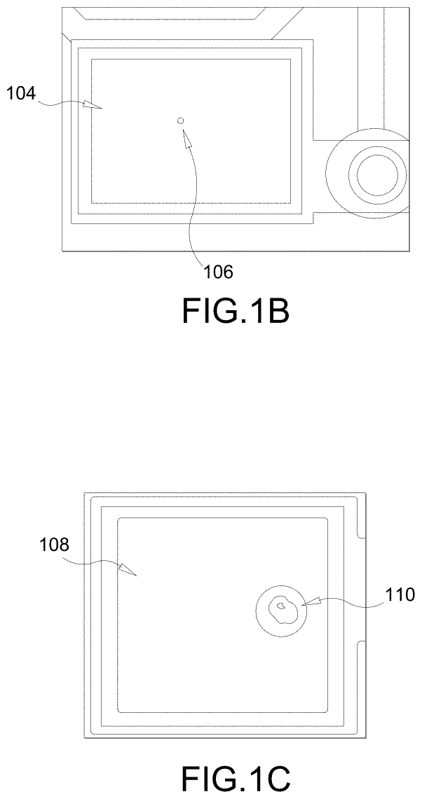

FIG. 1A is a graphic illustration of an integrated passive device (IPD) 100 including inductors 102 and capacitors 104. For example, the plurality of inductors 102 and capacitors 104 of IPD 100 may be used to implement circuits that may include one or more filters (e.g., bandpass, low pass, etc.). The IPD 100 may be formed as a passive-on-glass (POG) device and the capacitors 104 may be formed as metal insulator metal (MIM) capacitors. In conventional POG technology, there are no ESD protection circuits. A significant source of damage to IPD circuits is MIM capacitors damaged due to electrostatic ESD events. For example, in some studies, MIM capacitor damage is the number one failure category for the POG-related RF modules used for high frequencies (e.g., for 5G RF circuits). Low ESD threshold voltage was generally found to be the root cause of the MIM capacitor failures. Accordingly, ESD protection on-die would help mitigate this failure mode.

FIG. 1B is a graphic illustration of a portion of an IPD 100 illustrated in FIG. 1A including a MIM capacitor. As illustrated MIM capacitor 104 has damage 106 that is apparent from visual inspection. As noted above, the damage 106 is typically due to ESD damage.

FIG. 1C is a graphic illustration of another MIM capacitor. As illustrated MIM capacitor 108 has a damaged area 110 that is illustrated in more detail and is also apparent from visual inspection. As can be seen, the damaged area 110 due to ESD damage is more extensive than just a point failure. Accordingly, the circuit failure results in unacceptable die performance, which in turn reduces the effective yield of dies having filters and other circuits with MIM capacitors.

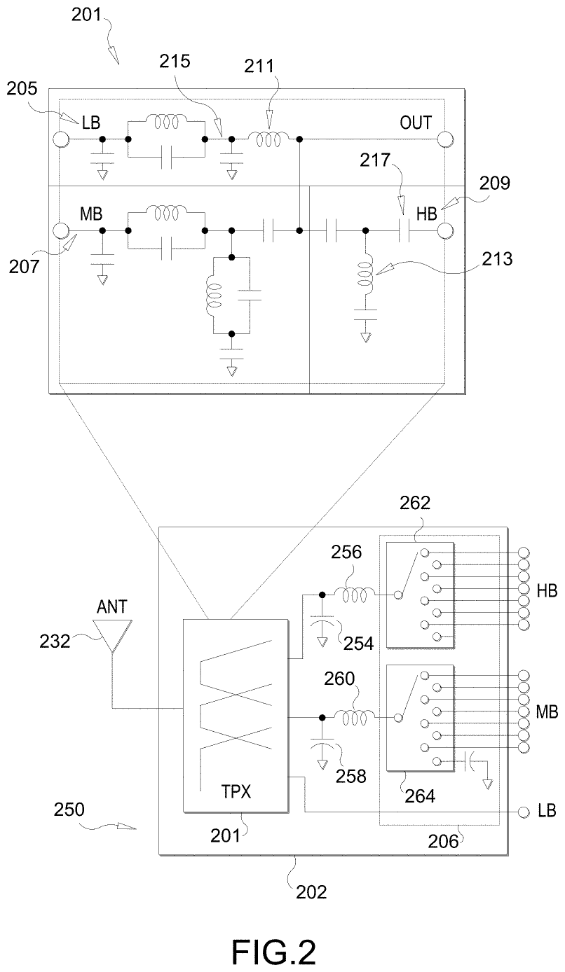

FIG. 2 is a schematic illustration of a circuit including an IPD, in this case a triplexer, according to one aspect of the disclosure. All or a portion (e.g., filters) of the circuit illustrated in FIG. 2 may be a protected circuit as disclosed herein. As noted above the plurality of inductors and capacitors may be used to form one or more filters that may be used in RF circuits, such as the illustrated triplexer. However, it will be appreciated that the various aspects disclosed are not limited to this circuit or the illustrated configuration. In FIG. 2 a triplexer (TPX) 201 has various inductors, e.g., 211 and 213, and various capacitors, e.g., 215 and 217, and is arranged to comprise a triplexer. The triplexer, in this case, can couple signals from 3 separate bands to a common node, via a high-band circuit 209, a middle-band circuit 207, and a low-band circuit 205. As can be seen in FIG. 2, the TPX 201 is largely composed of passive components (e.g., inductors and capacitors) arranged on a substrate (e.g., a glass substrate).

FIG. 2 further illustrates an example application of an electronic device as the TPX 201. For example, the TPX 201 may be formed as a passive-on-glass (POG) device. The TPX 201 may be integrated within a glass substrate 202. The glass substrate 202 may also include a semiconductor die 206 (e.g., a silicon semiconductor die). The semiconductor die 206 is integrated within the glass substrate 202. The semiconductor die 206 may include one or more active components, such as one or more transistors. In an illustrative example, the semiconductor die 206 includes multiple switches each including transistors. The semiconductor die 206 is coupled to the TPX 201.

FIG. 2 also depicts an illustrative example of a circuit diagram of a device 250 that includes the glass substrate 202. The device 250 further includes an antenna 232 coupled to the TPX 201. For example, the antenna 232 may be coupled to an input of the TPX 201. In the example of the device 250, TPX 201 includes a multiband bandpass filter. The multiband bandpass filter may include multiple bandpass filter circuits in accordance with a carrier aggregation technique. For example, the TPX 201 may include multiple bandpass filter circuits, such as a low-band filter circuit, a high-band filter circuit, and a middle-band filter circuit, as discussed above.

In addition to the TPX 201, the device 250 may include one or more other components, such as one or more inductors, one or more capacitors, one or more other components, or a combination thereof. For example, the TPX 201 may be coupled to a capacitor 254 and to an inductor 256. Further, the TPX 201 may be coupled to a capacitor 258 and to an inductor 260.

The semiconductor die 206 may include a plurality of switches. For example, the plurality of switches may include metal-oxide-semiconductor field-effect transistors (MOSFETs) formed within the semiconductor die 206. The plurality of switches may include a first set of one or more switches 262 coupled to the high-band circuit 209 of the TPX 201 and may further include a second set of one or more switches 264 coupled to the middle-band circuit 207 of the TPX 201. The semiconductor die 206 may also include one or more output terminals of an input/output (I/O) interface of the semiconductor die 206.

In one aspect, the TPX 201 is configured to generate multiple signals based on the signal from the antenna 232. In an illustrative example, the TPX 201 is configured to pass a high-band (HB) signal to a first output, a middle-band (MB) signal to a second output and a low-band (LB) signal to a third output. The HB signal, the MB signal, and the LB signal may correspond to a signal sent by a transmitter in a wireless communication system. In the illustrative example of FIG. 2, the third output (LB) is not connected to a switch. In other implementations, the third output may be coupled to one or more switches of the semiconductor die 206. The semiconductor die 206 may provide one or more selected signals to another device. For example, the semiconductor die 206 may provide one or more of the HB signal, the MB signal, and the LB signal to a particular device component, such as to a low noise amplifier (LNA) of a receiver device, as an example.

The arrangement of the passive and active components in FIG. 2 is provided for illustrative purposes only. There are any numbers of arrangements of passive components that can be used to form such a device. Additionally, it will be appreciated that these illustrations are provided solely to aid in explanation and for illustration of the various aspects disclosed and not limitation thereof, as the various aspects of the on-die ESD protection disclosed herein can be applied to various active or passive circuits.

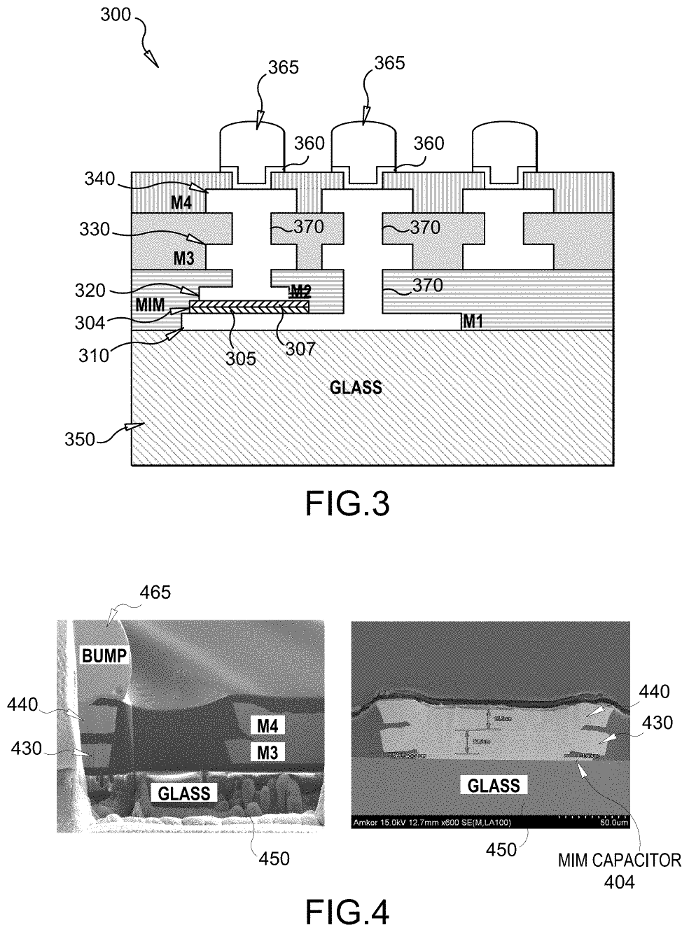

FIG. 3 is a graphical illustration of a cross-section of a portion of a die 300. As illustrated, the multilayer substrate includes a plurality of metal layers, such as M1 310, M2 320, M3 330 and M4 340 on a glass substrate 350. A plurality of through substrate vias 370, may be through-passivation vias in one example, and are used to electrically couple the metal layers (e.g., M1 310, M2 320, M3 330 and M4 340). A MIM capacitor 304 may be formed in die 300 and comprises a first metal layer (M1) 310, an insulating layer 307 and a second metal layer (M2) 320. An optional seed layer 305 (metal) may be used to smooth the first metal layer M1 310. A plurality of MIM capacitors 304 may be formed in die 300. The insulating layer 307 may be silicon nitride (SiN) compound or any other suitable insulating material. Additional metal layers (e.g., M3 330, M4 340) may be used for interconnections between the various layers using vias (e.g., 370) to connect the MIM capacitor 304 to external devices (e.g., via under bump metal layer (UBM) 360 and connector 365 (e.g., solder balls, solder bumps, copper posts, or other external connectors). Additionally, the various metal layers M1 310, M2 320, M3 330 and M4 340 and vias 370 may be used to connect the MIM capacitor 304 to internal components of die 300, such as other capacitors or inductors. It will be appreciated, that the two thick metal layers M3 330 and M4 340, which may be on the order of 8 um to 16 um in thickness, may be used to form the inductors (not illustrated, but in some aspects may be similar to inductors 102 in FIG. 1 and the ESD inductors described in the following). The inductors may be formed with the winding routed in the thick layers (e.g., M3 330, M4 340) for improved inductor Q factor and RF performance. It will be appreciated that these illustrations are provided solely to aid in explanation and for illustration of the various aspects disclosed and not limitation thereof. For example, there may be more than two thick metal layers, they may be located in different layers, and may be of different thicknesses. Likewise, the MIM capacitors 304 may be formed in different layers and may have additional insulating/dielectric layers and also additional conductive plates.

FIG. 4 is a graphical illustration of multiple cross-sections of portions of another die. The multiple images provide perspectives of the multilayer substrate including scaling of a plurality of metal layers, such as M3 430 and M4 440, connector 465, glass substrate 450 and MIM capacitor 404. It will be appreciated from these images that the illustrations of FIG. 3 were not to scale. The illustrations of FIG. 4 are also provided solely for illustration. Accordingly, it will be appreciated that these illustrations are provided solely to aid in explanation and to provide context of the various aspects disclosed and not limitation thereof. Accordingly, the various sizes and relationships of the various elements are not to be construed as limiting the various aspects disclosed herein.

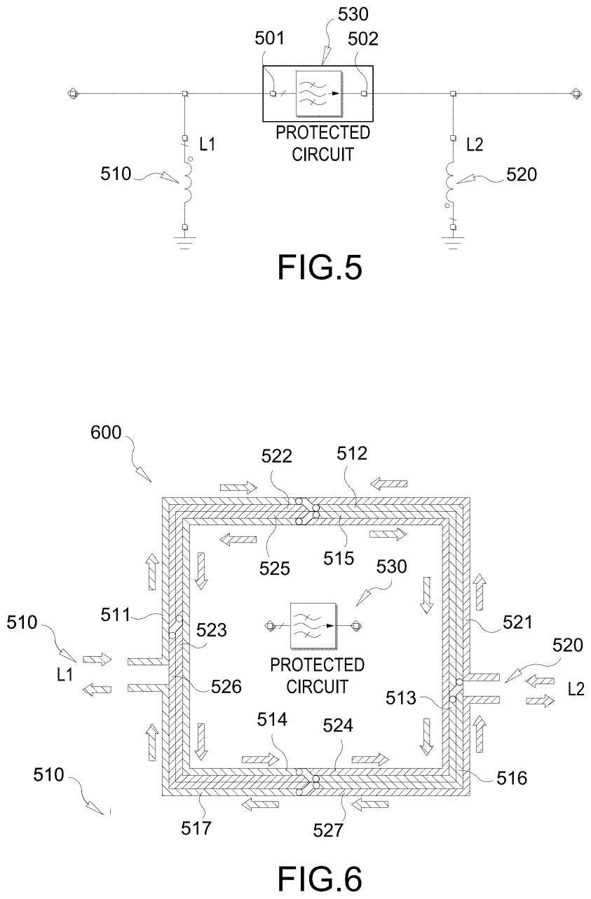

FIG. 5 is a simplified circuit diagram according to various aspects of the disclosure. As illustrated, there are two inductors, inductor 510 and inductor 520. Inductor 510 is electrically coupled to a first port 501 of the protected circuit 530. Inductor 520 is electrically coupled to a second port 502 of the protected circuit 530. The protected circuit 530 may be passive (e.g., IPD/POG devices, such as discussed above) or may include active devices. For example, inductors 510 (L1) and 520 (L2) may be electrically coupled to the input and output sides of the protected circuit 530 for ESD protection. In some aspects, inductor 510 (L1) and inductor 520 (L2) have substantially the same inductance. In some aspects, inductor 510 (L1) and inductor 520 (L2) each have an inductance greater than or equal to 10 nH. It will be appreciated that as long as both inductors 510, 520 are large enough (e.g., >10 nH) for a particular application, it is not necessary for both inductors 510, 520 to have the same inductance. For example, to maintain the performance of the protected circuit 530 (e.g., bandpass filter), an inductor should be sized to appear as an open circuit (e.g., high impedance at the operating frequencies, while have a low impedance for purposes of ESD protection).

FIG. 6 is a graphical representation of a layout of inductors for ESD protection according to various aspects of the disclosure, which may be referred to herein as ESD inductors. As illustrated in FIG. 6, an electronic device 600 includes inductor 510 (L1) and inductor 520 (L2) that each are routed in an outer area of the protected circuit 530 (e.g., a bandpass filter) and substantially encloses the protected circuit 530. Inductor 510 (L1) and inductor 520 (L2) are electromagnetically coupled to each other. To achieve electromagnetic coupling, inductor 510 (L1) and inductor 520 (L2) are routed in close proximity to each other. Routing in close proximity allows for better electromagnetic coupling of the inductors 510, 520. Further, inductor 510 (L1) and inductor 520 (L2) are configured in the layout in a way to make each current flow out of phase/in opposite directions, as illustrated by the arrows. By ensuring that the inductors 510, 520 are coupled with current flowing in opposite directions, the impact of inductor 510 (L1) and inductor 520 (L2) on the protected circuit 530 (e.g., band pass filter) is minimum. For example, the magnetic fields are cancelled out while the inductances (for ESD purpose) of inductor 510 (L1) and inductor 520 (L2) are maintained. However, it will be appreciated that other configurations may be used to ensure that the inductors 510, 520 are out of phase. For example, the inputs and outputs may have current flowing in the same direction, but the turns of the inductors 510, 520 may be configured so the electromagnetic fields are out of phase. Also, it will be appreciated that portions of the inductors 510, 520 may be in phase, so as used herein the first inductor 510 and second inductor 520 being out of phase does not require that all portions of the inductors 510, 520 are out of phase, but instead indicates that the inductors 510, 520 are electromagnetically coupled to substantially cancel the fields of the other.

In the illustrated example, inductor 510 (L1) has an input of the first inductor 510 that continues to a first winding portion 511 on an outer portion that crosses over to a second winding portion 512 on an outer center portion of the winding. A third winding portion 513 crosses over to an inner center portion of the winding. A fourth winding portion 514 crosses over to the inner portion of the winding. A fifth winding portion 515 crosses over to the inner center portion of the winding. A sixth winding portion 516 crosses over to the outer center portion of the winding. A seventh winding portion 517 crosses over to the outer portion of the winding and continues to an output of the inductor 510 (L1). This winding configuration results in two turns of the inductor 510 (L1).

Likewise, in the illustrated example, second inductor 520 (L2) winding has an input of the second inductor 520 that continues to a first winding portion 521 on an outer portion that crosses over to a second winding portion 522 on an outer center portion of the winding. A third winding portion 523 crosses over to an inner center portion of the winding. A fourth winding portion 524 crosses over to the inner portion of the winding. A fifth winding portion 525 crosses over to the inner center portion of the winding. A sixth winding portion 526 crosses over to the outer center portion of the winding. A seventh winding portion 527 crosses over to the outer portion of the winding and continues to an output of the inductor 520 (L2). This winding configuration results in two turns of the inductor 520 (L2).

As can be appreciated from the foregoing description and illustration, the windings of each inductor 510 (L1) and inductor 520 (L2) are intertwined by the various portions crossing over one another and this improves the electromagnetic coupling. For example, as discussed above, the inductor 510 (L1) and inductor 520 (L2) may be formed using thick metal layers (e.g., M3 330 and M4 340) and the crossover portions may be fabricated using vias (e.g., 370) to change layers and short traces to cross to the next winding portion. However, it will be appreciated that these illustrations are provided solely to aid in explanation and for illustration of the various aspects disclosed and not limitation thereof. For example, other winding routing configurations and number of turns for each inductor 510, 520 may be used. For example, in some applications only one turn may be used whereas in other applications more than two turns may be used or the windings could be routed concentric with each other (e.g., the inductor 510 and inductor 520 may not be intertwined), on adjacent layers or any other suitable configuration to allow for close coupling. Further, in some aspects, the first inductor and the second inductor are formed to partially enclose the protected circuit, the on-die protected circuit may more than two ports, and at least portions of the first inductor and the second inductor may be routed in phase, but other portions are out of phase, so that the total winding configuration substantially cancel the fields of each. Those skilled in the art will appreciate that circuit design considerations, such as the desired inductance, available area, and other design factors may impact the layout and number of turns.

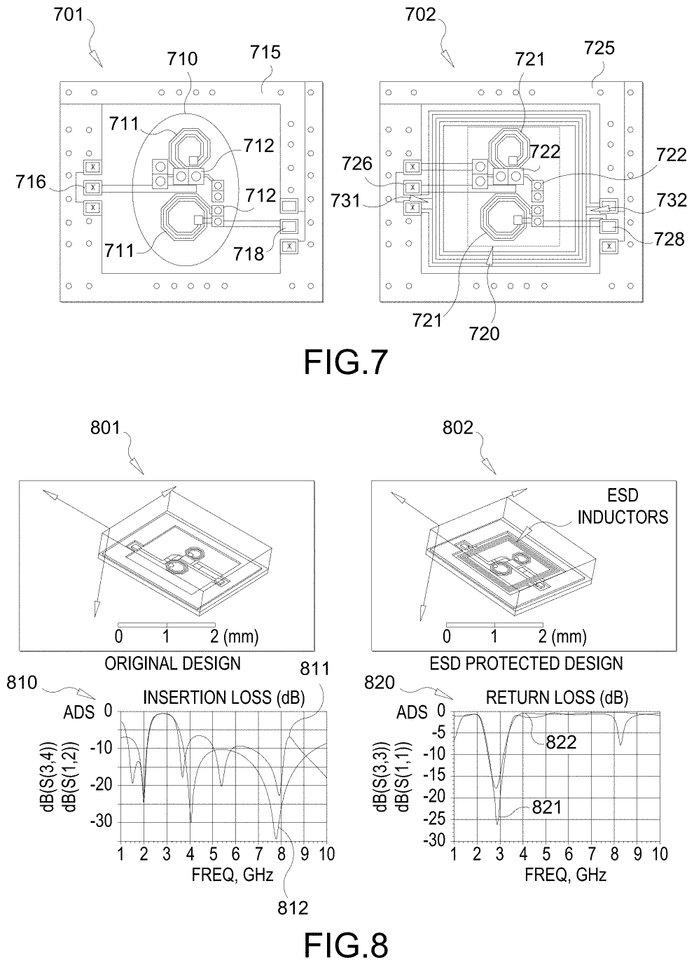

FIG. 7 illustrates a comparison of a conventional circuit layout of an electronic device 701 of on a portion of a die and a circuit layout of an electronic device 702 on a portion of a die with on-die ESD protection according to various aspects of the disclosure. Circuit 710 may be an IPD and may have a plurality of inductors 711 and MIM capacitors 712. Circuit 710 may be configured as a bandpass filter and may have a first port 716 (input) and second port 718 (output) to couple to other circuits and/or components on the die. The bandpass filter is also coupled to ground plane 715. Likewise, for the circuit layout of device 702, the protected circuit 720 may be an IPD and may have a plurality of inductors 721 and MIM capacitors 722. Protected circuit 720 may also be configured as a bandpass filter and may have a first port 726 (input) and a second port 728 (output). The bandpass filter is also coupled to a ground plane 725. However, in addition to the protected circuit 720, a first inductor 731 is also coupled to the first port 726 (input) of the protected circuit 720 and a second inductor 732 that is also coupled to the second port 728 (output) of the protected circuit 720. The first inductor 731 and the second inductor 732 are also coupled to the ground plane 725, which provides a path for current to flow for the ESD protection. Additionally, the first inductor 731 and the second inductor 732 are coupled to the respective ports of the protected circuit 720 and the ground plane 725 in a manner to ensure that current flow will be opposite in each inductor. The windings of the first inductor 731 and the second inductor 732 may be intertwined as illustrated and discussed in greater detail in the foregoing description of FIG. 6. It will be appreciated that these illustrations are provided solely to aid in explanation and for illustration of the various aspects disclosed and not limitation thereof. For example, other circuit types and configurations may be protected by the ESD inductors (first inductor 731 and second inductor 732) and the windings of the inductors may be routed differently. These are some examples among many design variations that will be recognized by those skilled in the art.

FIG. 8 is a graphical illustration of comparisons of simulations for a conventional circuit layout of electronic device 801 and a circuit layout of electronic device 802 with on-die ESD protection according to various aspects of the disclosure. The circuit layouts of electronic devices 801 and 802 are similar to circuit layouts of electronic devices 701 and 702, respectively, described in relation to FIG. 7. Accordingly, a rendition of the various features and details will not be provided. Graph 810 illustrates a comparison of the insertion loss for the two designs with curve 811 for the original circuit layout of electronic device 801 and curve 812 for the ESD protected circuit layout of electronic device 802. Graph 820 illustrates a comparison of the return loss for the two designs with curve 821 for the original circuit layout of device 801 and curve 822 for the ESD protected circuit layout of electronic device 802. As can be seen the return loss is about the same, for both circuit layouts of electronic devices 801, 802. Some additional resonances are presented due to the added layout pattern for the added inductors. The design layout can be tuned without much difficulty for E-performance. For example, tuning of the capacitors inside the IPD, based on electromagnetic (EM) simulation, can reduce the attenuation level in the rejection band to an acceptable level.

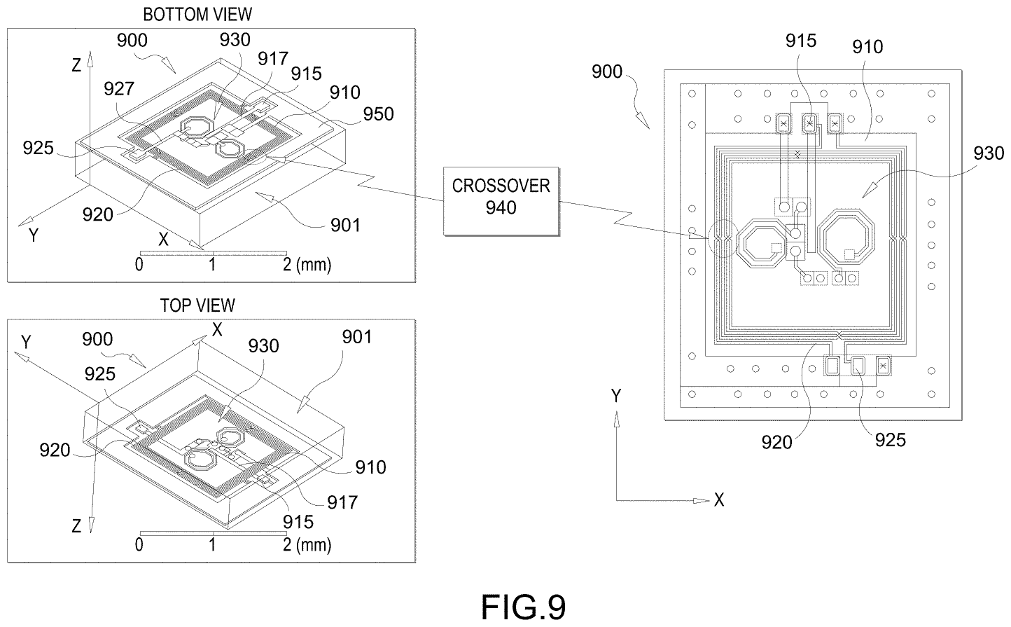

FIG. 9 is a graphical representation of a layout of inductors for ESD protection according to various aspects of the disclosure. As illustrated in FIG. 9, an electronic device 900 is shown in a top perspective view, a bottom perspective view and a plan view. The electronic device 900 is similar to electronic devices 600, 702 and 802 illustrated and discussed in the foregoing, so a detailed rendition of all elements will not be provided. The electronic device 900 includes a first inductor 910 and a second inductor 920 that each are routed in an outer area of the protected circuit 930 (e.g., a filter) disposed within die 901. The first inductor 910 and the second inductor 920 substantially encloses the protected circuit 930, which may include enclosing the protected circuit on all 4 sides, as illustrated. The first inductor 910 and the second inductor 920 are also routed in close proximity to each other. Further, the first inductor 910 and the second inductor 920 are configured to make each current flow out of phase/in opposite directions, as discussed above. However, it will be appreciated that other configurations may be used to ensure that the inductors 910, 920 are out of phase.

In the illustrated example, the winding of the first inductor 910 is coupled to a first port 915 and the winding of the second inductor 920 is coupled to a second port 925. As can be appreciated from the foregoing description and illustration, the windings of the first inductor 910 and the second inductor 920 are intertwined by the various portions crossing over one another and this improves the electromagnetic coupling. For example, as illustrated, the first inductor 910 and the second inductor 920 may be formed using metal layer M4 340. Likewise, as illustrated, the inductors 910, 920 of the protected circuit 930 are also formed in M4 340. The crossover portions may be fabricated using vias (e.g., 370) to change layers and short traces to cross to the next winding portion. For example, crossover portion 940 may be formed in a different metal layer (e.g., M3 330) than the first inductor 910 and the second inductor 920. The crossover portion 940 is illustrated in both the bottom perspective view and the plan view. The first inductor 910 and the second inductor 920 are coupled to the protected circuit 930 by traces in M3, 917 and 927, respectively. The first inductor 910 and the second inductor 920 are also coupled to a ground plane 950, which provides a path for current to flow for the ESD protection. Additionally, as illustrated the ground plane 950 may also be formed in M3 330 and/or M4 340. However, it will be appreciated that these illustrations are provided solely to aid in explanation and for illustration of the various aspects disclosed and not limitation thereof. For example, other winding routing configurations and number of turns for each inductor 910, 920 may be used. For example, there may be more or less than four metal layers and the formation of the first inductor 910, the second inductor 920 and the crossover portion 940 may be formed on other metal layers than those illustrated. Accordingly, those skilled in the art will appreciate that circuit design considerations, such as the desired inductance, available area, and other design factors may impact the layout, number of turns, etc.

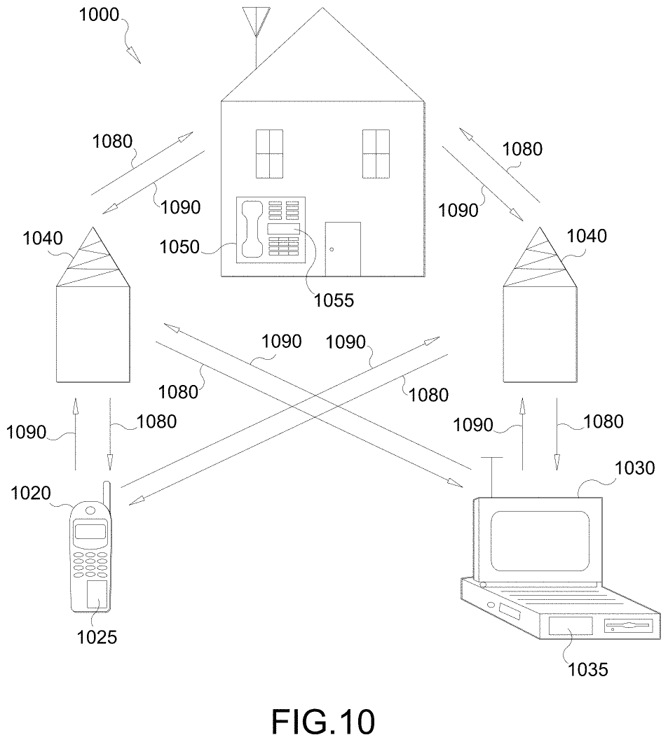

FIG. 10 illustrates an exemplary communication system 1000 in which devices may include one or more aspects of the disclosure, e.g., as described in reference to the foregoing description and related figures. For purposes of illustration, FIG. 10 shows three remote units 1020, 1030, and 1050 and two base stations 1040. It will be recognized that conventional wireless communication systems may have many more remote units and base stations. The remote units 1020, 1030, and 1050 include integrated circuits or other electronic devices 1025, 1035 and 1055, respectively, having one or more dies with on-die ESD protection in accordance with one or more of the disclosed exemplary aspects as claimed or as described in reference to the foregoing disclosure and illustrated in the related figures. FIG. 10 shows forward link signals 1080 from the base stations 1040 and the remote units 1020, 1030, and 1050 and reverse link signals 1090 from the remote units 1020, 1030, and 1050 to the base stations 1040.

In FIG. 10, the remote unit 1020 is shown as a mobile telephone, the remote unit 1030 is shown as a portable computer, and the remote unit 1050 is shown as a fixed location remote unit in a wireless local loop system. These are only examples, both in terms of quantity and type. For example, the remote units 1020, 1030 and 1050 may be one of, or any combination of a mobile phone, hand-held personal communication system (PCS) unit, portable data unit such as a personal data assistant (PDA), navigation device (such as GPS enabled devices), set top box, music player, video player, entertainment unit, fixed location data unit such as meter reading equipment, or any other device that receives or transmits wireless signals or any combination thereof. Although FIG. 10 illustrates remote units 1020, 1030 and 1050 according to aspects of the disclosure, the disclosure is not limited to these exemplary illustrated units. Aspects of the disclosure may be suitably employed in any device receiving or transmitting on multiple frequencies. For example, those skilled in the art will appreciate that aspects of the present disclosure may be incorporated into integrated devices, such as a mobile phone, which incorporate RF (Radio Frequency) communications in order to separate different frequency RF signal bands.

For example, a die with on-die ESD inductors and a protected circuit (e.g., bandpass filter) disclosed herein may be incorporated into a device that may include a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, or a device in an automotive vehicle. Further, it will be appreciated that aspects of the present disclosure may be used in a wide variety of devices and are not limited to the specific examples provide herein.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into a semiconductor chip. The chips may then be employed in devices described above.

In order to fully illustrate aspects of the design of the present disclosure, methods of fabrication are presented. Other methods of fabrication are possible, and the method of fabrication is presented only to aid understanding of the concepts disclosed herein.

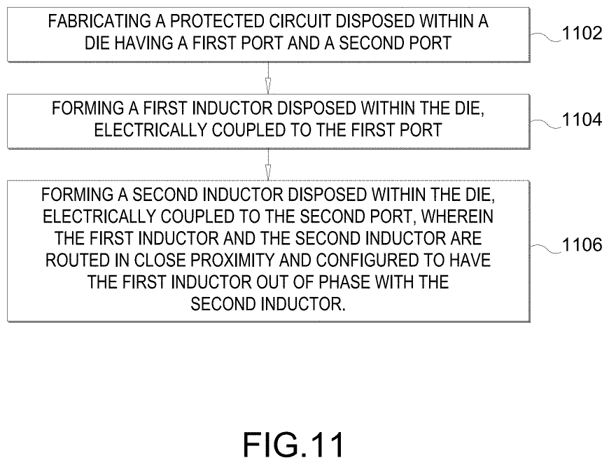

It will be appreciated from the foregoing that there are various methods for fabricating on-die ESD protection inductors according to aspects disclosed herein. FIG. 11 is a flowchart of a method for fabricating an electronic device with on-die ESD protection in accordance with at least one aspect disclosed herein. For example, block 1102 includes fabricating a protected circuit disposed within a die having a first port and a second port. Block 1104 includes forming a first inductor disposed within the die, electrically coupled to the first port. Block 1106 includes forming a second inductor disposed within the die, electrically coupled to the second port, wherein the first inductor and the second inductor are routed in close proximity and configured to have the first inductor out of phase with the second inductor. Conventional fabrication processes may be used, such as a copper plating process to form the on-die ESD inductors (e.g., inductors 510, 520, 731, 732, 910 and 920) along with forming the IPD or other devices being protected. It will be appreciated from the foregoing disclosure that additional processes for fabricating the various aspects disclosed herein will be apparent to those skilled in the art and a literal rendition of the processes discussed above will not be provided or illustrated in the included drawings.

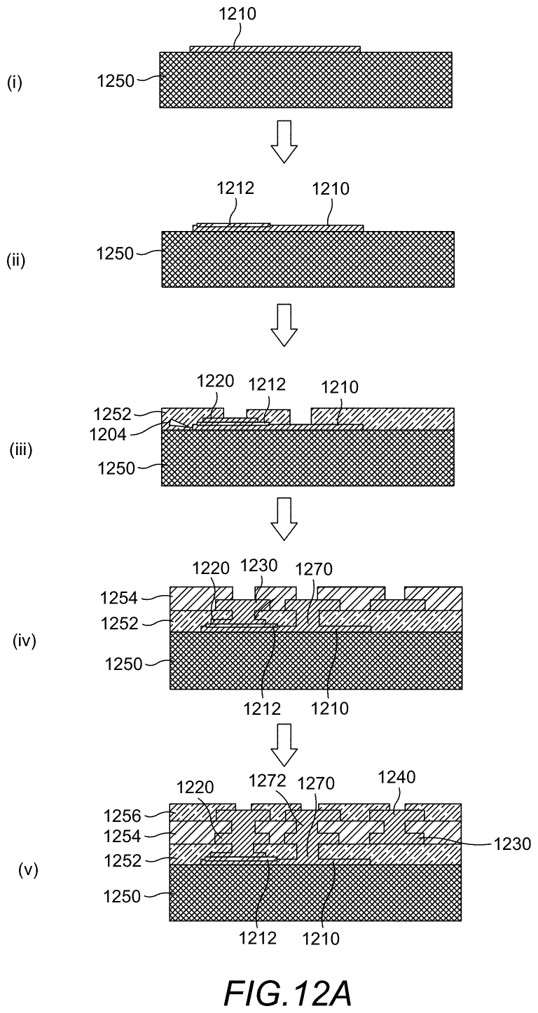

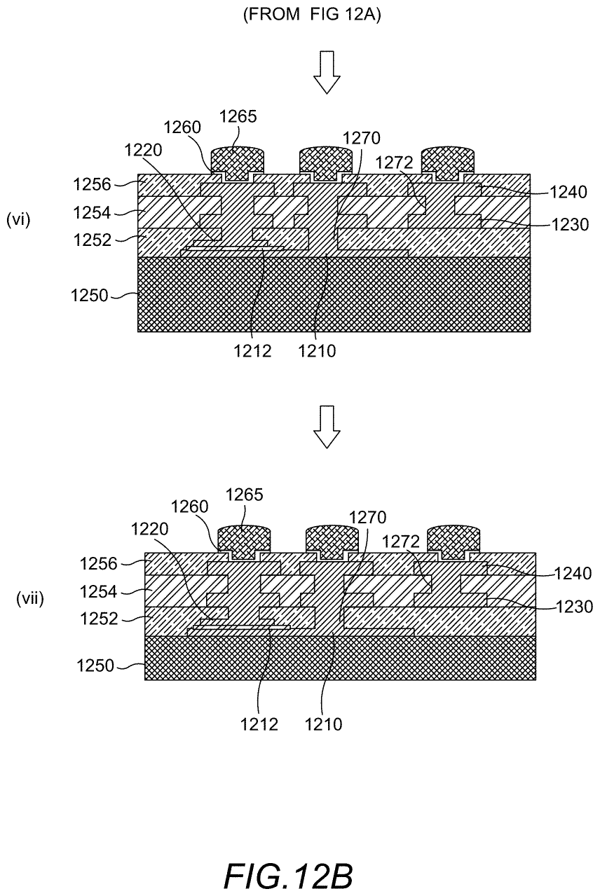

FIG. 12A is an illustration of portions of a fabrication process according to aspects of the disclosure. In a first portion (i), a substrate 1250 (e.g., glass, silicon, etc.) is provided and a first metal layer (M1) 1210 formed (e.g., by plating) on the substrate 1250. In a further portion of the process (ii), a silicon nitride (SiN) layer 1212 can be deposited (e.g., by a chemical vapor deposition (CVD) process). In a further portion of the process (iii), a second metal layer (M2) 1220 can be formed (e.g., by plating) over the SiN layer 1212. It will be appreciated that one or more MIM capacitors 1204 discussed herein may be formed by two metal structures (e.g., formed in the first metal layer 1210 and second metal layer 1220, respectively) with an insulating layer functioning as the dielectric, which may be the SiN layer 1212, as illustrated or any other suitable insulating material. The combined structure (e.g., first metal layer 1210, second metal layer 1220, SiN layer 1212 and substrate 1250) can be coated with a first polyimide layer 1252 and openings can be formed in the first polyimide layer 1252 to allow for via formation. In a further portion of the process (iv), a third metal layer (M3) 1230 can be formed (e.g., by plating) over the first polyimide layer 1252 and vias 1270 that were formed in the openings (noted previously). The vias 1270 may provide coupling between the first metal layer 1210 and/or the second metal layer 1220. The combined structure (e.g., first metal layer 1210, second metal layer 1220, SiN layer 1212, first polyimide layer 1252, third metal layer 1230 and substrate 1250) can be coated with a second polyimide layer 1254 and openings can be formed in the second polyimide layer 1254 to allow for via formation.

In a further portion of the process (v), a fourth metal layer (M4) 1240 can be formed (e.g., by plating) over the second polyimide layer 1254 and vias 1272 that were formed in the openings (noted previously) in the second polyimide layer 1254. The vias 1272 may provide coupling between the first metal layer 1210, the second metal layer 1220 and/or the third metal layer 1230. The combined structure (e.g., first metal layer 1210, second metal layer 1220, third metal layer 1230, SiN layer 1212, first polyimide layer 1252, second polyimide layer 1254, and substrate 1250) can be coated with a third polyimide layer 1256 and openings can be formed in the third polyimide layer 1256 to allow for UBM formation.

FIG. 12B is a further illustration of portions of a fabrication process according to aspects of the disclosure. In a further portion of the process (vi), the UBMs 1260 can be formed in the openings (noted previously) in the third polyimide layer 1256. The UBMs 1260 may provide coupling between the fourth metal layer 1240 and/or any of the other metal layers (e.g., 1210, 1220 and/or 1230) indirectly through the fourth metal layer 1240 and the vias (e.g., 1270 and 1272). Solder bumps/solder balls 1265 (or any other suitable connector) may be formed on the UBMs 1260 to allow connections to external devices. In a further portion of the process (vii), the substrate 1250 can be thinned to reduce the overall thickness of the device. For example, the substrate 1250 may be a glass substrate having an original thickness on the order of 1 millimeter (e.g., illustrated in the previous process portion (vi)) and after the thinning process, the glass substrate may have a thickness on the order of 100 to 300 micrometers. Additionally, although not expressly illustrated, it can be appreciated from the foregoing description and illustration, the windings of inductors (e.g., L1 and L2), may be formed from the various metal layers. For example, inductor L1 and inductor L2 may be formed as intertwined inductors by having various portions of the inductors crossing over one another. For example, a winding of inductor L1 can be formed at least in part on M3. A crossover coupled to the L1 winding can be formed by a via between layer M3 to M4 and a conductive trace on M4 crossing over to another via between M4 and M3 to continue with the L1 winding on M3. Alternatively, a winding of inductor L1 can be formed in part on M3 having a crossover coupled to the L1 winding. The crossover can be formed by a via between layers M3 to M4 and a conductive trace on M4 crossing over to continue with the winding on M4. Accordingly, it will be appreciated that the intertwined inductors may reside substantially in one layer or may be formed on adjacent layers. However, it will be appreciated that these illustrations are provided solely to aid in explanation and for illustration of the various aspects disclosed and not limitation thereof. It will be appreciated that additional processes for fabricating various aspects disclosed will be recognized by those skilled in the art. Further, it will be appreciated that the simplified illustrated configurations, materials and/or descriptions are provided merely to aid in the explanation of the various aspects disclosed herein. Accordingly, the forgoing illustrative examples and associated figures should not be construed to limit the various aspects disclosed and claimed herein.

In accordance with the various aspects disclosed herein, at least one first example aspect includes an electronic device (e.g., 600, 702, 802, 900, etc.). The electronic device has a protected circuit (e.g., 530, 720, 930, etc.) disposed within a die having a first port (e.g., 501, 726, 915, etc.) and a second port (e.g., 502, 728, 925, etc.). A first inductor (e.g., 510, 731, 910, etc.) is disposed within the die, electrically coupled to the first port. A second inductor (e.g., 520, 732, 920, etc.) is disposed within the die, electrically coupled to the second port. The first inductor and the second inductor are routed in close proximity and are configured so the first inductor is out of phase with the second inductor. The first inductor and the second inductor are both formed around the protected circuit. Among the various technical advantages the various aspects disclosed provide, in at least some aspects, the feature(s) first and second inductors formed on-die provides one or more paths for current to flow for the ESD protection, while the die is undergoing processing, which reduces die failure and improves yields as discussed herein. Additionally, by winding the inductors out of phase, the magnetic fields are cancelled out and any electromagnetic interference on the protected circuit is reduced. Other technical advantages will be recognized from various aspects disclosed herein and these technical advantages are merely provided as examples and should not be construed to limit any of the various aspects disclosed herein.

Further aspects may include one or more of the following features discussed in the various example aspects. In example 2, the electronic device of example 1 may include the first inductor and the second inductor having the same inductance or substantially the same inductance. In example 3, the electronic device of examples 1 or 2 may include the first inductor and the second inductor each having an inductance greater than or equal to 10 nH. In example 4, the electronic device of one of the previous examples, may include the first inductor and the second inductor both being routed around the protected circuit to enclose the protected circuit or substantially enclose the protected circuit. In example 5, the electronic device of one of the previous examples, include where the first inductor and the second inductor are both connected to a ground plane in the die. In example 6, the electronic device of one of the previous examples, include where the first inductor and the second inductor are both routed in a manner to produce current flow in the first inductor opposite to current flow in the second inductor. In example 7, the electronic device of one of the previous examples, include where the first inductor and the second inductor each have multiple turns. In example 8, the electronic device of example 7 includes where the first inductor and the second inductor turns are intertwined. In example 9, the electronic device of example 8 further includes a plurality of crossover portions that route windings of at least one of the first inductor or the second inductor to different winding paths to intertwine the first and second inductors. In example 10, the electronic device of one of the previous examples, include where the protected circuit is an active device. In example 7, the electronic device of one of the previous examples, include where the protected circuit is a passive device. In example 12, the electronic device of example 11 includes where the protected circuit is an integrated passive device. In example 13, the electronic device of example 12 includes where the protected circuit is a bandpass filter. In example 14, the electronic device of example 13 includes where the bandpass filter has at least one inductor and at least one metal insulator metal (MIM) capacitor. In example 15, the electronic device of example 14 includes where at least one of the first inductor or the second inductor is electrically coupled to the at least one MIM capacitor. In example 16, the electronic device of one of the previous examples, include where the first port is an input and the second port is an output. In example 17, the electronic device of one of the previous examples, include where the first inductor and the second inductor are formed using adjacent metal layers in a multilayer substrate of the die. In example 18, the electronic device of example 17 includes where the adjacent metal layers are thick metal layers. In example 19, the electronic device of example 18 includes where the adjacent metal layers are in a range of about 8 um to 16 um in thickness. In example 20, the electronic device of one of the previous examples, include where the electronic device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

In further example aspects, example 21 includes a method for fabricating an electronic device. The method includes fabricating a protected circuit disposed within a die having a first port and a second port. The method further includes forming a first inductor disposed within the die and being electrically coupled to the first port. The method further includes forming a second inductor disposed within the die, and being electrically coupled to the second port. The first inductor and the second inductor are routed in close proximity and configured to have the first inductor out of phase with the second inductor. The first inductor and the second inductor are both formed around the protected circuit. In example 22, the method of example 21 includes where the first inductor and the second inductor have the same inductance or substantially the same inductance. In example 23, the method of example 22 includes where the first inductor and the second inductor each have an inductance greater than or equal to 10 nH. In example 24, the method of any one of examples 21 to 23 further include routing the first inductor and the second inductor to produce current flow in the first inductor opposite to current flow in the second inductor. In example 25, the method of any one of examples 21 to 24 include where the first inductor and the second inductor are each formed with multiple turns. In example 26, the method of any one of examples 21 to 25 include where the, wherein the first inductor and the second inductor are turns are intertwined. In example 27, the method of any one of examples 21 to 26, further includes forming a plurality of crossover portions to route windings of the first inductor and/or the second inductor to different winding paths to intertwine the first and second inductors. In example 28, the method of any one of examples 21 to 23 include where the first inductor and the second inductor are formed using adjacent metal layers in a multilayer substrate of the die. In example 29, the method of example 28 includes where the adjacent metal layers are thick metal layers. In example 30, the method of example 22 includes where adjacent metal layers are in a range of about 8 um to 16 um in thickness.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, embodiments disclosed herein can include a non-transitory computer-readable media embodying a method for fabricating the various electronic devices having one or more dies with on-die ESD protection. Accordingly, the disclosure is not limited to illustrated examples as any means for performing the functionality described herein are contemplated by the present disclosure.

While the foregoing disclosure shows various illustrative embodiments, it should be noted that various changes and modifications could be made herein without departing from the scope of the teachings of the present disclosure as defined by the appended claims. The functions, steps and/or actions of the method claims in accordance with the embodiments of the disclosure described herein need not be performed in any particular order. Furthermore, although elements of the present disclosure may be described or claimed in the singular, the plural is contemplated unless limitation to the singular is explicitly stated.

1. An electronic device comprising:
a protected circuit disposed within a die having a first port and a second port;
a first inductor disposed within the die, electrically coupled to the first port; and
a second inductor disposed within the die, electrically coupled to the second port, wherein the first inductor and the second inductor are routed in close proximity and are configured so the first inductor is out of phase with the second inductor and wherein the first inductor and the second inductor are both formed around the protected circuit.

2. The electronic device of claim 1, wherein the first inductor and the second inductor have substantially a same inductance.

3. The electronic device of claim 1, wherein the first inductor and the second inductor each have an inductance greater than or equal to 10 nH.

4. The electronic device of claim 1, wherein the first inductor and the second inductor are both routed around the protected circuit to substantially enclose the protected circuit.

5. The electronic device of claim 1, wherein the first inductor and the second inductor are both connected to a ground plane in the die.

6. The electronic device of claim 1, wherein the first inductor and the second inductor are both routed in a manner to produce current flow in the first inductor opposite to current flow in the second inductor.

7. The electronic device of claim 1, wherein the first inductor and the second inductor each have multiple turns.

8. The electronic device of claim 7, wherein the first inductor and the second inductor turns are intertwined.

9. The electronic device of claim 8 further comprising a plurality of crossover portions that route windings of at least one of the first inductor or the second inductor to different winding paths to intertwine the first and second inductors.

10. The electronic device of claim 1, wherein the protected circuit is an active device.

11. The electronic device of claim 1, wherein the protected circuit is a passive device.

12. The electronic device of claim 11, wherein the protected circuit is an integrated passive device.

13. The electronic device of claim 11, wherein the protected circuit is a bandpass filter.

14. The electronic device of claim 13, wherein the bandpass filter has at least one inductor and at least one metal insulator metal (MIM) capacitor.

15. The electronic device of claim 14, wherein at least one of the first inductor or the second inductor is electrically coupled to the at least one MIM capacitor.

16. The electronic device of claim 1, wherein the first port is an input and the second port is an output.

17. The electronic device of claim 1, wherein the first inductor and the second inductor are formed using adjacent metal layers in a multilayer substrate of the die.

18. The electronic device of claim 17, wherein the adjacent metal layers are thick metal layers.

19. The electronic device of claim 18, wherein the adjacent metal layers are in a range of about 8 um to 16 um in thickness.

20. The electronic device of claim 1, wherein the electronic device is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

21. A method for fabricating an electronic device comprising:
fabricating a protected circuit disposed within a die having a first port and a second port;
forming a first inductor disposed within the die, electrically coupled to the first port; and
forming a second inductor disposed within the die, electrically coupled to the second port, wherein the first inductor and the second inductor are routed in close proximity and configured to have the first inductor out of phase with the second inductor, wherein the first inductor and the second inductor are both formed around the protected circuit.

22. The method of claim 21, wherein the first inductor and the second inductor have substantially the same inductance.

23. The method of claim 22, wherein the first inductor and the second inductor each have an inductance greater than or equal to 10 nH.

24. The method of claim 21, further comprising:
routing the first inductor and the second inductor to produce current flow in the first inductor opposite to current flow in the second inductor.

25. The method of claim 21, wherein the first inductor and the second inductor are each formed with multiple turns.

26. The method of claim 25, wherein the first inductor and the second inductor are turns are intertwined.

27. The method claim 26 further comprising:
forming a plurality of crossover portions to route windings of the first inductor and/or the second inductor to different winding paths to intertwine the first and second inductors.

28. The method of claim 21, wherein the first inductor and the second inductor are formed using adjacent metal layers in a multilayer substrate of the die.

29. The method of claim 28, wherein the adjacent metal layers are thick metal layers.

30. The method of claim 29, wherein the adjacent metal layers are in a range of about 8 um to 16 um in thickness.
